(19) United States
(12) Patent Application Publication
(10) Pub. No.: US 2024/0312871 A1
(43) Pub. Date: Sep. 19, 2024

(54) HEAT RADIATING MEMBER AND SEMICONDUCTOR MODULE

(71) Applicant: NIDEC CORPORATION, Kyoto (JP)

(72) Inventor: Kazuhiro NISHIKAWA, Kyoto (JP)

(21) Appl. No.: 18/522,244

(22) Filed: Nov. 29, 2023

(30) Foreign Application Priority Data
Mar. 17, 2023 (JP) 2023-042635

(51) Int. Cl. H01L 23/473; H01L 25/18

(52) U.S. Cl. CPC H01L 23/473; H01L 25/18

(57) ABSTRACT

A heat radiating member includes: a base part in a plate shape that extends in a first direction along a refrigerant flow direction and in a second direction orthogonal to the first direction; a heat radiating fin part formed by stacking a plurality of fins in the second direction, the plurality of fins protruding from the base part toward a first side; and a plurality of flow path channels formed in the second direction in the heat radiating fin part, a first flow path channel through which the refrigerant passes through a region facing a semiconductor element, the semiconductor element being disposed on a second side in the base part; and a second flow path channel through which the refrigerant does not pass, and the first flow path channel having a lower average flow path resistance than the second flow path channel.

### CROSS-REFERENCE TO RELATED APPLICATIONS

The present invention claims priority under 35 U.S.C. § 119 to Japanese Patent Application No. 2023-042635 filed on Mar. 17, 2023, the entire content of which is incorporated herein by reference.

### FIELD OF THE INVENTION

The present disclosure relates to a heat radiating member.

### BACKGROUND

Heat radiating members are conventionally used for cooling heating elements. The heat radiating members each includes a base part and a plurality of fins. The plurality of fins protrudes from the base part. When a refrigerant such as water flows between adjacent fins in the plurality of fins, heat of the heating element moves to the refrigerant.

In recent years, a technique for cooling a semiconductor element such as an insulated gate bipolar transistor (IGBT) using a heat radiating member has become important in in-vehicle applications and the like.

### SUMMARY

An exemplary heat radiating member of the present disclosure includes: a base part in a plate shape that extends in a first direction along a refrigerant flow direction and in a second direction orthogonal to the first direction, and has a thickness in a third direction orthogonal to the first direction and the second direction; a heat radiating fin part formed by stacking a plurality of fins in the second direction, the plurality of fins protruding from the base part toward a first side in the third direction and extending in the first direction; and a plurality of flow path channels formed in the second direction in the heat radiating fin part, the plurality of flow path channels being formed by the corresponding fins adjacent to each other in the second direction, and including a first flow path channel through which the refrigerant passes through a region facing a semiconductor element in the third direction, the semiconductor element being disposed on a second side in the third direction of the base part, and a second flow path channel through which the refrigerant does not pass, and the first flow path channel having a lower average flow path resistance than the second flow path channel.

The above and other elements, features, steps, characteristics and advantages of the present disclosure will become more apparent from the following detailed description of the preferred embodiments with reference to the attached drawings.

### BRIEF DESCRIPTION OF THE DRAWINGS

FIG. 1 is a perspective view of a heat radiating member according to an exemplary embodiment of the present disclosure;

FIG. 2 is a schematic plan view of a heat radiating member according to an exemplary embodiment of the present disclosure;

FIG. 3 is a plan view illustrating a layout of flow path channels in a heat radiating fin part;

FIG. 4 is a perspective view of various fins;

FIG. 5 is a perspective view illustrating an example of an opening;

FIG. 6 is a perspective view illustrating an example of a cutout;

FIG. 7 is a perspective view illustrating an example of a slit;

FIG. 8 is a perspective view illustrating an example of a single spoiler;

FIG. 9 is a perspective view illustrating an example of a double spoiler;

FIG. 10 is a perspective view illustrating a first modification of a protrusion;

FIG. 11 is a perspective view illustrating a second modification of the protrusion;

FIG. 12 is a perspective view illustrating partial structure of a heat radiating fin part according to a modification; and

FIG. 13 is a plan view similar to FIG. 2.

### DETAILED DESCRIPTION

Hereinafter, an exemplary embodiment of the present disclosure will be described with reference to the drawings.

The drawings each indicate a first direction as an X direction in which X1 indicates a first side in the first direction and X2 indicates a second side in the first direction. The first direction is along a direction F in which a refrigerant W flows, and F1 indicates a downstream side and F2 indicates an upstream side. The first direction is orthogonal to a second direction as a Y direction in which Y1 indicates a first side in the second direction, and Y2 indicates a second side in the second direction. The first direction and the second direction are orthogonal to a third direction as a Z direction in which Z1 indicates a first side in the third direction, and Z2 indicates a second side in the third direction. The above-described orthogonal also includes intersection at an angle slightly shifted from 90 degrees. Each of the above-described directions does not limit a direction when a heat radiating member is incorporated in various devices.

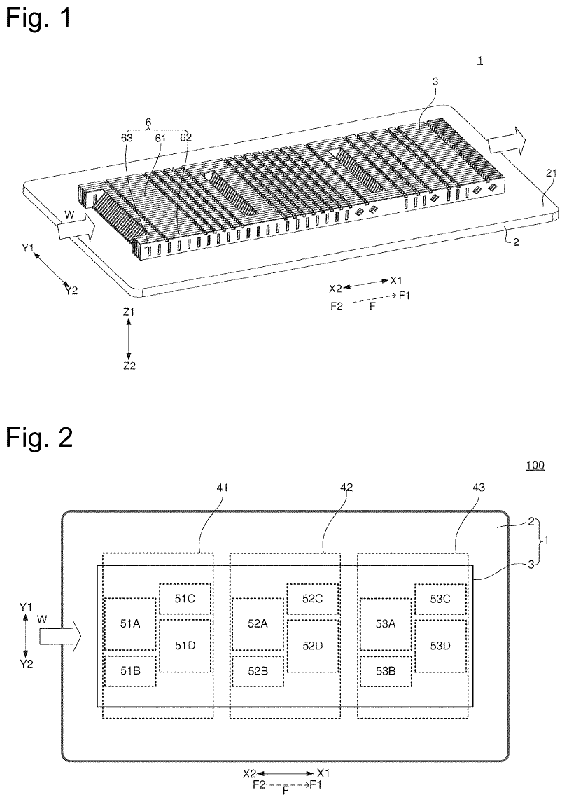

FIG. 1 is a perspective view of a heat radiating member 1 according to an exemplary embodiment of the present disclosure. FIG. 2 is a schematic plan view of the heat radiating member 1 according to the exemplary embodiment of the present disclosure as viewed from the first side in the third direction to the second side in the third direction. FIG. 2 also illustrates insulating circuit boards 41 to 43 disposed on the second side in the third direction of the heat radiating member 1 and semiconductor elements 51A to 51D, 52A to 52D, and 53A to 53D (referred to below as 51A and the like). The heat radiating member 1, the insulating circuit boards 41 to 43, and the semiconductor elements 51A and the like constitute a semiconductor module 100.

The heat radiating member 1 can be installed in a liquid cooling jacket (not illustrated), and includes a base part 2 and a heat radiating fin part 3.

The base part 2 has a plate shape that extends in the first direction and the second direction and has a thickness in the third direction. The base part 2 is made of a metal having high thermal conductivity, such as a copper alloy.

The heat radiating fin part 3 is configured as a so-called stacked fin by disposing a plurality of fins (fin plates) 6 in the second direction. The fins 6 are each formed of a metal plate extending in the first direction, and formed of a copper plate, for example. The heat radiating fin part 3 is fixed to a surface 21 of the base part 2 on the first side in the third direction by brazing, for example. That is, the heat radiating member 1 includes the heat radiating fin part 3 formed by stacking the plurality of fins 6 in the second direction, the fins 6 protruding from the base part 2 toward the first side in the third direction and extending in the first direction.

The plurality of fins 6 includes fins 61 and 62, and a fin 63, as described later. The fin 63 is a fin plate located at an end on the second side in the second direction, and has a flat plate shape unlike the fins 61 and 62. Detailed structure of the fins 61 and 62 will be described later.

The refrigerant W flows into the heat radiating fin part 3 from the second side (upstream side) in the first direction to flow through a flow path channel formed between the fins 6 adjacent in the second direction toward the first side (downstream side) in the first direction, and is discharged from the heat radiating fin part 3 toward the first side in the first direction.

The semiconductor elements 51A and the like are heating elements to be cooled by the heat radiating member 1. The semiconductor element 51A and the like are provided in an inverter provided in a traction motor for driving wheels of a vehicle, for example. The semiconductor elements 51A, 51D, 52A, 52D, 53A, and 53D are each a transistor such as an IGBT. The semiconductor elements 51B, 51C, 52B, 52C, 53B, and 53C are each a diode.

The insulating circuit boards 41 to 43 are disposed on the base part 2 on the second side in the third direction. The insulating circuit boards 41, 42, and 43 are disposed in this order from the second side in the first direction toward the first side in the first direction.

The semiconductor elements 51A to 51D are disposed on the insulating circuit board 41 on the second side in the third direction. The semiconductor element 51A is disposed on the first side in the second direction from the semiconductor element 51B. The semiconductor element 51D is disposed on the second side in the second direction from the semiconductor element 51C. A set of the semiconductor elements 51C and 51D is disposed on the first side in the first direction from a set of the semiconductor elements 51A and 51B. The set of the semiconductor elements 51A and 51B and the set of semiconductor elements 51D and 51C are disposed while being displaced from each other in the second direction.

The semiconductor elements 52A to 52D are disposed on the insulating circuit board 42 on the second side in the third direction. The semiconductor element 52A is disposed on the first side in the second direction from the semiconductor element 52B. The semiconductor element 52D is disposed on the second side in the second direction from the semiconductor element 52C. A set of the semiconductor elements 52C and 52D is disposed on the first side in the first direction from a set of the semiconductor elements 52A and 52B. The set of the semiconductor elements 52A and 52B and the set of semiconductor elements 52D and 52C are disposed while being displaced from each other in the second direction.

The semiconductor elements 53A to 53D are disposed on the insulating circuit board 43 on the second side in the third direction. The semiconductor element 53A is disposed on the first side in the second direction from the semiconductor element 53B. The semiconductor element 53D is disposed on the second side in the second direction from the semiconductor element 53C. A set of the semiconductor elements 53C and 53D is disposed on the first side in the first direction from a set of the semiconductor elements 53A and 53B. The set of the semiconductor elements 53A and 53B and the set of semiconductor elements 53D and 53C are disposed while being displaced from each other in the second direction.

As a result, the set of the semiconductor elements 51A and 51B, the set of the semiconductor elements 51D and 51C, the set of the semiconductor elements 52A and 52B, the set of the semiconductor elements 52D and 52C, the set of the semiconductor elements 53A and 53B, and the set of the semiconductor elements 53D and 53C are disposed in this order from the second side in the first direction toward the first side in the first direction.

That is, the semiconductor elements 51A and the like are disposed on the base part 2 on the second side in the third direction.

The insulating circuit board and the semiconductor elements are not limited to the layout described above. The insulating circuit board is not limited in plural number as described above, and may be single. The semiconductor element is not limited in plural number as described above, and may be single. The semiconductor elements are not limited in two types as described above, and may be in one type, or three or more types.

The semiconductor elements 51A and the like generate heat that is transferred to the fins 6 through the insulating circuit boards 41 to 43 and the base part 2, and that moves to the refrigerant W to cool the semiconductor elements 51A and the like.

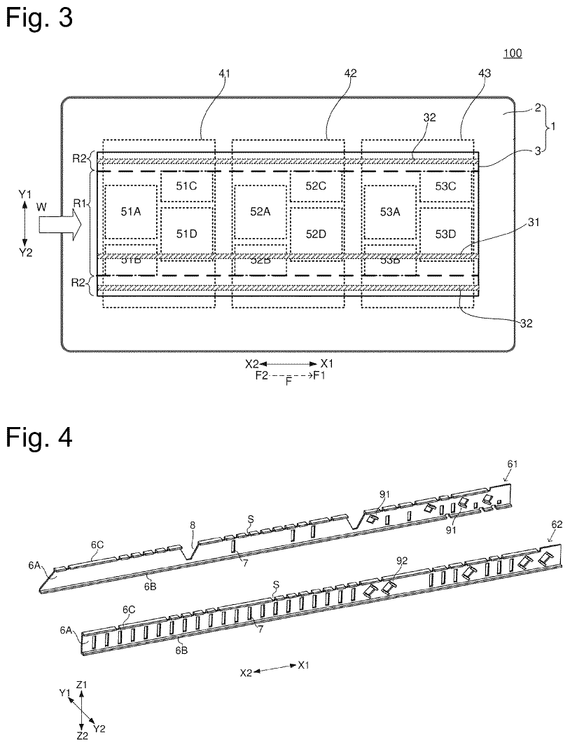

The heat radiating fin part 3 is provided with a plurality of flow path channels formed in the second direction by the fins 6 adjacent to each other in the second direction. FIG. 3 is a plan view illustrating a layout of flow path channels in the heat radiating fin part 3. FIG. 3 is based on the plan view of FIG. 2.

A first flow path channel 31 allows the refrigerant W to pass through a region facing the semiconductor elements 51A and the like in the third direction. FIG. 3 illustrates the first flow path channel 31 disposed in a first region R1 between ends of the semiconductor elements 51B, 52B, and 53B on the second side in the second direction and ends of the semiconductor elements 51C, 52C, and 53C on the first side in the second direction.

FIG. 3 illustrates the first flow path channel 31 divided into seven sub-channels described below in order from the second side in the second direction. A first sub-channel allows the refrigerant W to pass through a region facing the semiconductor elements 51B, 52B, and 53B in the third direction. A second sub-channel allows the refrigerant W to pass through a region facing the semiconductor elements 51B, 51D, 52B, 52D, 53B, and 53D in the third direction. A third sub-channel allows the refrigerant W to pass through a region facing the semiconductor elements 51D, 52D, and 53D in the third direction. A fourth sub-channel allows the refrigerant W to pass through a region facing the semiconductor elements 51A, 51D, 52A, 52D, 53A, and 53D in the third direction. A fifth sub-channel allows the refrigerant W to pass through a region facing the semiconductor elements 51A, 52A, and 53A in the third direction. A sixth sub-channel allows the refrigerant W to pass through a region facing the semiconductor elements 51A, 51C, 52A, 52C, 53A, and 53C in the third direction. A seventh sub-channel allows the refrigerant W to pass through a region facing the semiconductor elements 51C, 52C, and 53C in the third direction. FIG. 3 illustrates only one of sub-channels of the first flow path channel 31 as an example in the first region R1, the one being the second sub-channel.

A second flow path channel 32 does not allow the refrigerant W to pass through a region facing the semiconductor elements 51A and the like in the third direction. FIG. 3 illustrates the second flow path channel 32 disposed in a second region R2 including a region on the second side in the second direction from ends of the semiconductor elements 51B, 52B, and 53B on the second side in the second direction and a region on the first side in the second direction from ends of the semiconductor elements 51C, 52C, and 53C on the first side in the second direction. FIG. 3 illustrates the second flow path channel 32 in only one of the regions included in the second regions R2, as an example.

The present embodiment causes the plurality of sub-channels of the first flow path channel 31 in the first region R1 to have a lower average flow path resistance than the plurality of sub-channels of the second flow path channel 32 in the second region R2. The first flow path channel 31 has the average flow path resistance of a value obtained by dividing a total of flow path resistances of the plurality of sub-channels of the first flow path channel 31 in the first region R1 by the number of the plurality of sub-channels of the first flow path channel 31. The second flow path channel 32 has the average flow path resistance of a value obtained by dividing a total of flow path resistances of the plurality of sub-channels of the second flow path channel 32 in the second region R2 by the number of the plurality of sub-channels of the second flow path channel 32.

As described above, the first flow path channel 31 has a lower average flow path resistance than the second flow path channel 32. As a result, the first flow path channel 31 has a larger average amount of refrigerant flowing therethrough than the second flow path channel 32, and thus cooling performance of the semiconductor elements 51A and the like facing the first flow path channel 31 in the third direction can be improved.

Although it is conceivable to provide a structure that generates a turbulent flow in a flow path to improve cooling performance, an examination of the inventors of the present application has resulted in that when a large number of structures for generating a turbulent flow are provided in the first flow path channel disposed parallel to the second flow path channel, flow path resistance increases to cause the refrigerant to be less likely to flow, and thus an effect of improving the cooling performance is not recognized. Then, the present inventors have found that when the second flow path channel has a higher average flow path resistance than the first flow path channel disposed parallel to the second flow path channel, the amount of refrigerant flowing through the first flow path channel increases, and thus the cooling performance is improved.

The flow path resistance can be adjusted by the structure of the fin 6. FIG. 4 is a perspective view of the fins 61 and 62. The fin 61 is one of the plurality of fins 6 included in the first region R1. The first region R1 includes a plurality of fins 61 disposed in the second direction. The fin 62 is one of the plurality of fins 6 included in the second region R2. The second region R2 includes a plurality of fins 62 disposed in the second direction.

As illustrated in FIG. 4, each of the fins 61, 62 includes a side plate part 6A extending in the first direction, a bottom plate part 6B extending toward the second side in the second direction at an end of the side plate part 6A on the second side in the third direction, and a top plate part 6C extending toward the second side in the second direction at an end the side plate part 6A on the first side in the third direction. The top plate part 6C is provided by bending a tip of the side plate part 6A. However, besides this, the top plate part 6C may be provided by attaching a plate-like member to the tip of the side plate part 6A.

As illustrated in FIG. 4, the fin 61 is provided with an opening 7, a cutout 8, and a single spoiler 91. The fin 62 is provided with an opening 7 and a double spoiler 92. The flow path resistance can be adjusted by the opening 7, the cutout 8, the single spoiler 91, and the double spoiler 92.

As especially illustrated in FIG. 4, the fin 62 includes more openings 7 in number than the fin 61. The fin 62 also includes more protrusions in number with the double spoiler 92 than the fin 61 with the single spoiler 91. The single spoiler 91 includes one protrusion, and the double spoiler 92 includes two protrusions. Such a structure causes the fin 62 to cause a larger flow path resistance than the fin 61.

When the fins 61 and 62 each include a slit S formed in the top plate part 6C as illustrated in FIG. 4, the flow path resistance is adjusted by the slit S.

The fins 61 and 62 may be mixed in at least one of the first region R1 and the second region R2. Even such a case is allowed as long as the first flow path channel 31 has a lower average flow path resistance than the second flow path channel 32.

Hereinafter, each component capable of adjusting the flow path resistance in the fin 6 will be specifically described.

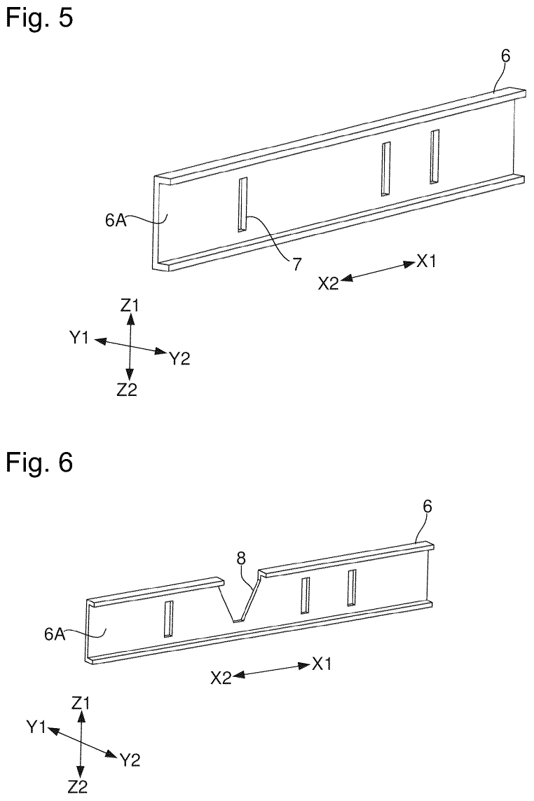

FIG. 5 is a perspective view illustrating an example of the opening 7. The fin 6 includes the side plate part 6A extending in the first direction. The opening 7 provided passing through the side plate part 6A in the second direction adjusts the flow path resistance of the flow path channel. The opening 7 not only destroys a boundary layer of a flow developed along the side plate part 6A but also promotes a turbulent flow. The opening 7 enables a structure for adjusting the flow path resistance to be easily manufactured.

FIG. 6 is a perspective view illustrating an example of the cutout 8. When the cutout 8 recessed toward the second side in the third direction is formed in an end of the side plate part 6A on the first side in the third direction, the cutout 8 adjusts the flow path resistance of the flow path channel. The cutout 8 not only destroys a boundary layer of a flow developed along the side plate part 6A but also promotes a turbulent flow. The cutout 8 enables a structure for adjusting the flow path resistance to be easily manufactured.

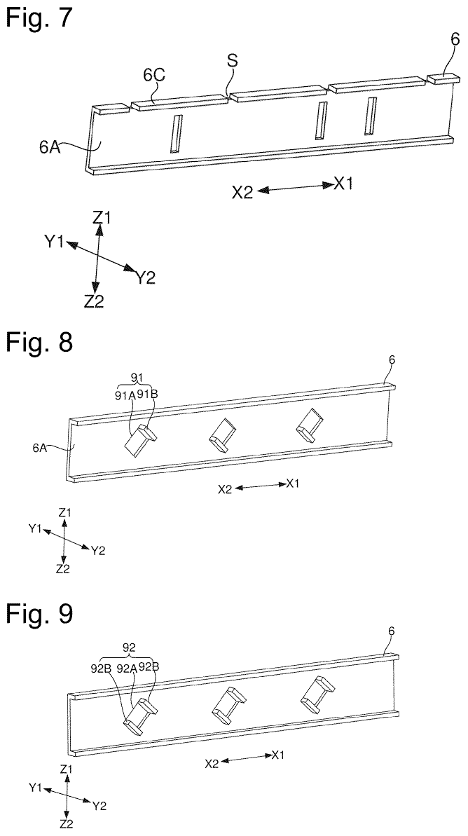

FIG. 7 is a perspective view illustrating an example of the slit S. The fin 6 includes a side plate part 6A extending in the first direction and the top plate part 6C extending in the second direction at the end of the side plate part 6A on the first side in the third direction. When the slit S is formed in the top plate part 6C, the flow path resistance of the flow path channel is adjusted by the slit S. The slit S not only destroys a boundary layer of a flow developed along the top plate part 6C but also promotes a turbulent flow. The slit S enables a structure for adjusting the flow path resistance to be easily manufactured.

FIG. 8 is a perspective view illustrating an example of the single spoiler 91. The single spoiler 91 includes an opening 91A and a protrusion 91B. The protrusion 91B protrudes in the second direction from a first side of the opening 91A in a rectangular shape. That is, the single spoiler 91 includes only one protrusion 91B. The protrusion 91B is inclined toward the second side in the third direction and the first side in the first direction. The protrusion 91B is provided from a first side of the opening 91A on the first side in the third direction or on the second side in the third direction.

FIG. 9 is a perspective view illustrating an example of the double spoiler 92. The double spoiler 92 includes an opening 92A and protrusions 92B. The protrusion 92B protrudes in the second direction from each of two sides of the opening 91A in a rectangular shape. That is, the double spoiler 92 includes two protrusions 92B. The protrusion 92B is inclined toward the second side in the third direction and the first side in the first direction.

As described above, the fin 6 includes the protrusions 91B and 92B protruding in the second direction from parts of the peripheral parts of the opening 91A and 92A, respectively. This structure allows each of the protrusions 91B and 92B to face in the direction in which the refrigerant W flows, so that a turbulent flow is likely to be generated and a large flow path resistance is likely to be set, thereby improving cooling performance.

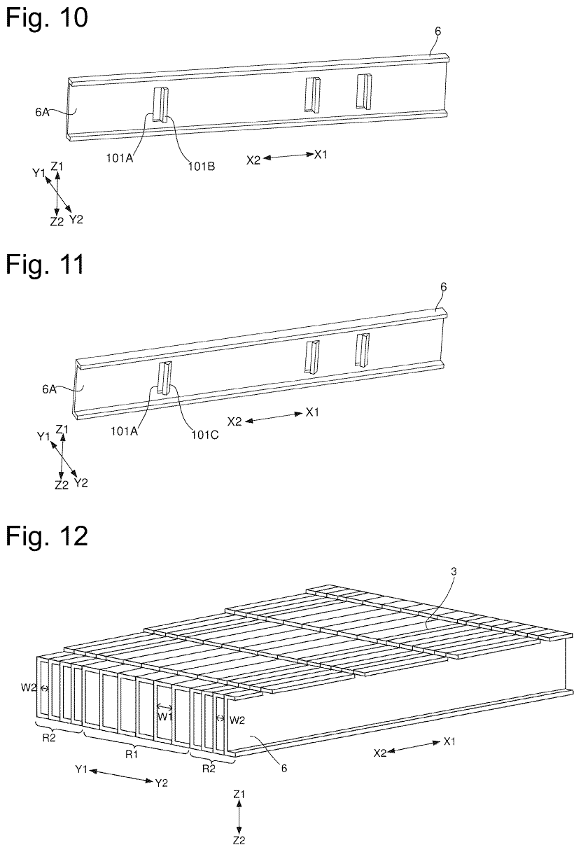

FIG. 10 is a perspective view illustrating a first modification of the protrusion. FIG. 10 illustrates the fin 6 including an opening 101A and a protrusion 101B. The opening 101A passes through the side plate part 6A of the fin 6 in the second direction. The opening 101A in a quadrangular shape includes two opposing sides extending parallel to the third direction. The protrusion 101B protrudes in the second direction from a first side of the two sides, the first side being on the first side in the first direction. The protrusion 101B extends parallel to the third direction and protrudes at an angle of 90 degrees with respect to the side plate part 6A.

FIG. 11 is a perspective view illustrating a second modification of the protrusion. FIG. 11 illustrates the fin 6 including the opening 101A and a protrusion 101C. As a difference from FIG. 10 described above, the protrusion 101C protrudes at an angle of 45 degrees with respect to the side plate part 6A.

Even the protrusions 101B and 101C facilitate adjustment to a large flow path resistance.

FIG. 12 is a perspective view illustrating a partial structure of a heat radiating fin part 3 according to a modification. A flow path channel has a flow path width that is a second direction width between fins 6 adjacent to each other in the second direction. FIG. 12 illustrates the structure in which a first flow path channel 31 has a larger average flow path width than a second flow path channel 32. The average flow path width of the first flow path channel 31 is an average value of flow path widths W1 of a plurality of sub-channels of the first flow path channel 31 disposed in the first region R1. The average flow path width of the second flow path channel 32 is an average value of flow path widths W2 of a plurality of sub-channels of the second flow path channel 32 disposed in the second region R2.

As described above, the flow path resistance can be adjusted by changing the flow path width. In particular, adjustment design is facilitated by adjusting the flow path width together with each component described above capable of adjusting the flow path resistance.

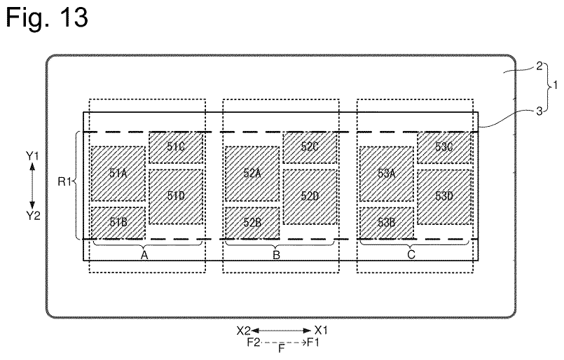

FIG. 13 is a plan view as with FIG. 2 described above. However, FIG. 13 indicates each region facing the semiconductor elements 51A and the like in the third direction by hatching. The first region R1 satisfies a relationship of FRA<FRB<FRC, where FRA is an average flow path resistance in the hatched region in a group A of the semiconductor elements 51A to 51D, FRB is an average flow path resistance in the hatched region in a group B of the semiconductor elements 52A to 52D, and FRC is an average flow path resistance in the hatched region in a group C of the semiconductor elements 53A to 53D. That is, the first flow path channel 31 includes a region including a region on a downstream side and a region on an upstream side, and facing the plurality of semiconductor elements (groups A to C) in the third direction, the plurality of semiconductor elements being disposed in the first direction, and the region on the downstream side having a higher average flow path resistance than the region on the upstream side.

The cooling performance is improved as the flow path resistance increases, so that even the refrigerant increased in temperature on the downstream side can suppress degradation of the cooling performance.

For example, the hatched region corresponding to each the set of semiconductor elements 51C and 51D, the set of 52C and 52D, and the set of 53C and 53D, which are disposed on the downstream side of the corresponding groups A, B, and C, may have a higher average flow path resistance than the hatched region corresponding to each of the set of semiconductor elements 51A and 51B, the set of 52A and 52B, and the set of 53A and 53B, which are disposed on the upstream side thereof.

The embodiment of the present disclosure has been described above. The scope of the present disclosure is not limited to the above embodiment. The present disclosure can be implemented by making various changes to the above embodiment without departing from the gist of the invention. The matters described in the above embodiment can be optionally combined together, as appropriate, as long as there is no inconsistency.

As described above, a heat radiating member according to an aspect of the present disclosure has a structure (first structure) including: a base part in a plate shape that extends in a first direction along a refrigerant flow direction and in a second direction orthogonal to the first direction, and has a thickness in a third direction orthogonal to the first direction and the second direction; a heat radiating fin part formed by stacking a plurality of fins in the second direction, the plurality of fins protruding from the base part toward a first side in the third direction and extending in the first direction; and a plurality of flow path channels formed in the second direction in the heat radiating fin part, the plurality of flow path channels being formed by the corresponding fins adjacent to each other in the second direction, and including a first flow path channel through which the refrigerant passes through a region facing a semiconductor element in the third direction, the semiconductor element being disposed on a second side in the third direction of the base part, and a second flow path channel through which the refrigerant does not pass, and the first flow path channel having a lower average flow path resistance than the second flow path channel (first structure).

The first structure may be configured such that the fins each include a side plate part extending in the first direction, and the side plate part is provided with an opening passing through the side plate part in the second direction to adjust flow path resistance of the flow path channel (second structure).

The second structure may be configured such that the fins each include a protrusion protruding in the second direction from a part of a peripheral part of the opening (third structure).

Any one of the first to third structures may be configured such that the fins each include a side plate part extending in the first direction, and the side plate part includes an end on the first side in the third direction, the end being provided with a cutout recessed toward the second side in the third direction to adjust the flow path resistance of the flow path channel (fourth structure).

Any one of the first to fourth structures may be configured such that the fins each include a side plate part extending in the first direction and a top plate part extending in the second direction at the end of the side plate part on the first side in the third direction, and the top plate part is provided with a slit to adjust the flow path resistance of the flow path channel (fifth structure).

Any one of the first to fifth structures may be configured such that the flow path channel has a flow path width that is a second direction width between the fins adjacent to each other in the second direction, and the first flow path channel has a larger average flow path width than the second flow path channel (sixth structure).

Any one of the first to sixth structures may be configured such that the first flow path channel includes a region including a region on a downstream side and a region on an upstream side, and facing a plurality of the semiconductor elements in the third direction, the plurality of the semiconductor elements being disposed in the first direction, and the region on the downstream side having a higher average flow path resistance than the region on the upstream side (seventh structure).

A semiconductor module according to an aspect of the present disclosure includes the heat radiating member having any one of the first to seventh structures and the semiconductor element (eighth structure).

The present disclosure can be used for cooling semiconductor elements for various applications.

Features of the above-described preferred embodiments and the modifications thereof may be combined appropriately as long as no conflict arises.

While preferred embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A heat radiating member comprising:
a base part in a plate shape that extends in a first direction along a refrigerant flow direction and in a second direction orthogonal to the first direction, and has a thickness in a third direction orthogonal to the first direction and the second direction;
a heat radiating fin part formed by stacking a plurality of fins in the second direction, the plurality of fins protruding from the base part toward a first side in the third direction and extending in the first direction; and
a plurality of flow path channels formed in the second direction in the heat radiating fin part,
the plurality of flow path channels being formed by the corresponding fins adjacent to each other in the second direction, and including:
a first flow path channel through which the refrigerant passes through a region facing a semiconductor element in the third direction, the semiconductor element being disposed on a second side in the third direction of the base part; and
a second flow path channel through which the refrigerant does not pass, and
the first flow path channel having a lower average flow path resistance than the second flow path channel.

2. The heat radiating member according to claim 1, wherein
the fins each include a side plate part extending in the first direction, and
the side plate part is provided with an opening passing through the side plate part in the second direction to adjust flow path resistance of the flow path channel.

3. The heat radiating member according to claim 2, wherein
the fins each include a protrusion protruding in the second direction from a part of a peripheral part of the opening.

4. The heat radiating member according to claim 1, wherein
the fins each include a side plate part extending in the first direction, and
the side plate part includes an end on the first side in the third direction, the end being provided with a cutout recessed toward the second side in the third direction to adjust the flow path resistance of the flow path channel.

5. The heat radiating member according to claim 1, wherein
the fins each include a side plate part extending in the first direction and a top plate part extending in the second direction at the end of the side plate part on the first side in the third direction, and
the top plate part is provided with a slit to adjust the flow path resistance of the flow path channel.

6. The heat radiating member according to claim 1, wherein
the flow path channel has a flow path width that is a second direction width between the fins adjacent to each other in the second direction, and
the first flow path channel has a larger average flow path width than the second flow path channel.

7. The heat radiating member according to claim 1, wherein
the first flow path channel includes a region including a region on a downstream side and a region on an upstream side, and facing a plurality of the semiconductor elements in the third direction, the plurality of the semiconductor elements being disposed in the first direction, and the region on the downstream side having a higher average flow path resistance than the region on the upstream side.

8. A semiconductor module comprising:
the heat radiating member according to claim 1; and
the semiconductor element.
